(19) United States
(12) Patent Application Publication
(10) Pub. No.: US 2026/0076178 A1
(43) Pub. Date: Mar. 12, 2026

(54) SEMICONDUCTOR DEVICE INCLUDING ELECTRIC FUSE AND RESISTOR ELEMENTS AND MANUFACTURING METHOD THEREOF

(71) Applicant: RENESAS ELECTRONICS CORPORATION, Tokyo (JP)

(72) Inventors: Naohito SUZUMURA, Tokyo (JP); Hiromichi TAKAOKA, Tokyo (JP); Kenichiro SONODA, Tokyo (JP); Hideaki TSUCHIYA, Tokyo (JP); Yasutaka NAKASHIBA, Tokyo (JP)

(21) Appl. No.: 19/392,403

(22) Filed: Nov. 18, 2025

Related U.S. Application Data
(62) Division of application No. 17/847,952, filed on Jun. 23, 2022.

(30) Foreign Application Priority Data
Sep. 2, 2021 (JP) 2021-143192

(51) Int. Cl. H01L 23/525; H01C 7/00; H01L 23/522; H10D 86/85

(52) U.S. Cl. CPC H10W 20/493; H01C 7/006; H10D 86/85; H10W 20/498

(57) ABSTRACT

An electric fuse element has a first portion, a second portion arranged on one end of the first portion, and a third portion arranged on the other end of the first portion. A resistor element is arranged separately from the electric fuse element. A material of each of the electric fuse element and the resistor element has silicon metal or nickel chromium. The electric fuse element and the resistor element are arranged in an upper layer of the first wiring and in lower layer of the second wiring. A wiring width of the second portion and a wiring width of the third portion are larger than a wiring width of the first portion.

### CROSS-REFERENCE TO RELATED APPLICATIONS

This Application is a Divisional Application of U.S. patent application Ser. No. 17/847,952, filed on Jun. 23, 2022, which claims the benefit of foreign priority to Japanese Patent Application No. 2021-143192 filed on Sep. 2, 2021, the entire contents of each of which are hereby incorporated by reference.

### BACKGROUND

The present embodiments relate to a semiconductor device and a method of manufacturing the same.

There are disclosed techniques listed below.
[Patent Document 1] Japanese Unexamined Patent Application Publication No. 2011-155192

Patent Document 1 discloses a semiconductor device having a configuration in which the resistivity does not vary even when stressed, for example. In Patent Document 1, a metal resistor element layer is formed in a region between the passivation film and the uppermost layer aluminum wiring. Thus, high precision resistor element with the less fluctuation of the resistance value due to the mold stress after the packaging process can be realized, it is possible to form a high precision analog circuit.

### SUMMARY

However, further stabilization of characteristics and miniaturization are required in semiconductor device in which various elements are mixed.

Other objects and novel features will become apparent from the description of this specification and the accompanying drawings.

According to a semiconductor device according to one embodiment, a first metal film includes: a first portion; a second portion arranged on one end of the first portion; and a third portion arranged one the other end of the first portion. A second metal film is arranged separately from the first metal film. A material of each of the first metal film and the second metal film includes silicon metal or nickel chromium. The first metal film and the second metal film are arranged in an upper layer of the first wiring and in a lower layer of the second wiring. Each of at least one part of the second portion and at least one part of the third portion has a wiring width larger than a wiring width of the first portion.

According to a semiconductor device according to other embodiments, a material of an electric fuse element that can be a target of fusing removal when replacing a specific circuit portion with a redundant circuit portion includes a silicon metal film or nickel chromium.

According to a method of manufacturing a semiconductor device according to one embodiment, it includes the following steps. A first wiring is formed. A first metal film having a first portion, a second portion arranged on one end of the first portion, and a third portion arranged on the other end of the first portion is formed in upper layer of the first wiring. A second metal film separated from the first metal film is formed in an upper layer of the first wiring. A second wiring is formed in an upper layer of the first metal film and the second metal film. A material of each of the first metal film and the second metal film includes silicon metal or nickel chromium. The first metal film is formed such that each of at least one part of the second portion and at least one part of the third portion has a wiring width larger than a wiring width of the first portion. The first metal film and the second metal film are formed at the same time.

According to the above embodiments, it is possible to realize a semiconductor device and method of manufacturing the same which have stable characteristics and are suitable for miniaturization.

### BRIEF DESCRIPTION OF THE DRAWINGS

FIG. 1 is a plan view showing a configuration of a semiconductor device in a chip-state according to one embodiment.

FIG. 2 is a plan view schematically showing a configuration of a semiconductor chip in which a redundant circuit is formed.

FIG. 3 is a diagram showing a circuit configuration having an electric fuse.

FIG. 4A is a cross-sectional view along IVA-IVA line of FIG. 5A, and FIG. 4B is a cross-sectional view along IVB-IVB line of FIG. 5B.

FIG. 5A is a plan view showing a configuration of a resistor element, and FIG. 5B is a plan view showing a configuration of an electric fuse element.

FIG. 6A is a plan view showing the configuration of the resistor element, and FIG. 6B is a plan view showing the configuration of the electric fuse element, in which a second wiring is omitted and a first wiring FI8 is added.

FIG. 7 is a plan view showing a configuration in which resistor elements are connected in parallel.

FIG. 8A is a cross-sectional view showing a configuration in which the resistor element is electrically connected to the second wiring, and FIG. 8B is a cross-sectional view showing a configuration in which the electric fuse element is electrically connected to the second wiring.

FIG. 9A is a cross-sectional view showing a first step in a method of manufacturing a semiconductor device including the resistor element according to one embodiment, and FIG. 9B is a cross-sectional view showing a first step in a method of manufacturing a semiconductor device including the electric fuse element according to one embodiment.

FIG. 10A is a cross-sectional view showing a second step in a method of manufacturing the semiconductor device including the resistor element according to one embodiment, and FIG. 10B is a cross-sectional view showing a second step in a method of manufacturing the semiconductor device including the electric fuse element according to one embodiment.

FIG. 11A is a cross-sectional view showing a third step in a method of manufacturing the semiconductor device including the resistor element according to one embodiment, and FIG. 11B is a cross-sectional view showing a third step in a method of manufacturing the semiconductor device including the electric fuse element according to one embodiment.

FIG. 12A is a cross-sectional view showing a fourth step in a method of manufacturing the semiconductor device including the resistor element according to one embodiment, and FIG. 12B is a cross-sectional view showing a fourth step in a method of manufacturing the semiconductor device including the electric fuse element according to one embodiment.

FIG. 13A is a cross-sectional view showing a fifth step in a method of manufacturing the semiconductor device including the resistor element according to one embodiment, and FIG. 13B is a cross-sectional view showing a fifth step in a method of manufacturing the semiconductor device including the electric fuse element according to one embodiment.

### DETAILED DESCRIPTION

Hereinafter, embodiments of the present disclosure will be described in detail with reference to the drawings. In the specification and drawings, the same or corresponding components are denoted by the same reference numerals, and a repetitive description thereof is not repeated. In the drawings, for convenience of explanation, the configuration or manufacturing method may be omitted or simplified. Also, at least some of the embodiments and each modified example may be arbitrarily combined with each other.

A semiconductor device of the embodiments described below is not limited to a semiconductor chip, may be a semiconductor wafer prior to being divided into semiconductor chips, also may be a semiconductor package in which the semiconductor chip is sealed with a resin. Also, a plan view in this specification means a viewpoint viewed from a direction perpendicular to the surface of the semiconductor substrate.

### Configuration of Semiconductor Device in Chip-State

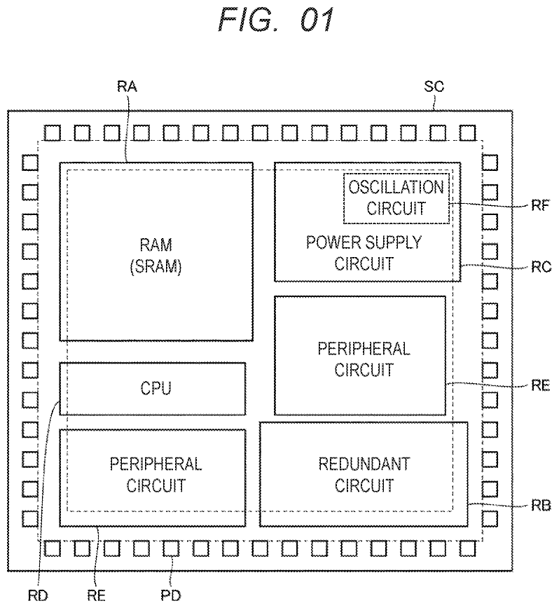

First, a configuration in a chip-state will be described with reference to FIG. 1 as a configuration of a semiconductor device in the present embodiment.

As shown in FIG. 1, the semiconductor device SC in the present embodiment is, for example, a microcomputer. The semiconductor device SC is, for example, in a chip-state and has a semiconductor substrate. Electric elements are arranged on and above the semiconductor substrate. The semiconductor device SC includes, for example, a RAM (Random Access Memory) region RA, a redundant circuit region RB, a power supply circuit region RC, a CPU (Central Processing Unit) region RD, and a peripheral circuit region RE. The power supply circuit region RC has, for example, an oscillation circuit region RF. The semiconductor device SC has a plurality of pad electrodes PD. Each of the plurality of pad electrodes PD is electrically connected to an electric element arranged in the semiconductor device SC.

Oscillation circuit is arranged in the oscillation circuit region RF. The oscillation circuit, for example, generates an output signal of a predetermined oscillation period by oscillation operation by repetition of charging and discharging of the capacitive element. The oscillation circuit is, for example, a HOCO (High-speed On-Chip Oscillator) circuit, but may be a LOCO (Low-speed On-Chip Oscillator) circuit and may include both a HOCO circuit and a LOCO circuit.

The oscillation circuit has a constant current circuit for outputting a signal of a constant voltage level, the constant current circuit includes a resistor element. The oscillation circuit has a differential amplifier circuit, also includes a resistor element in the differential amplifier circuit. The resistor element is also included in other circuits.

Spare redundant circuit portion is arranged in the redundant circuit region RB. Spare redundant circuit portion has the same function as the specific circuit portion having a predetermined function. In order to replace the specific circuit portion in the redundant circuit portion, an electric fuse which is to be fused and removed is provided.

### Configuration and Function of the Redundant Circuit Portion and the Electric Fuse

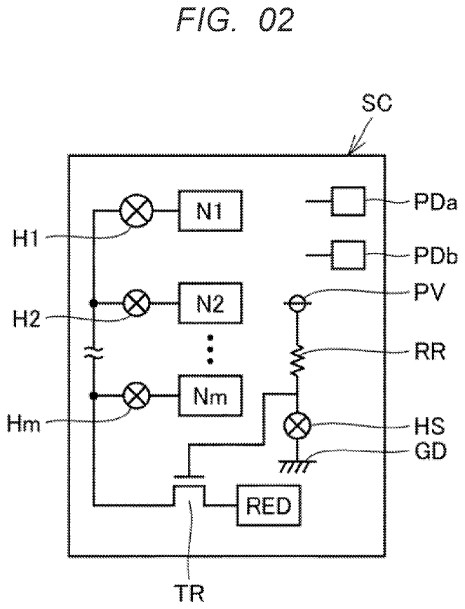

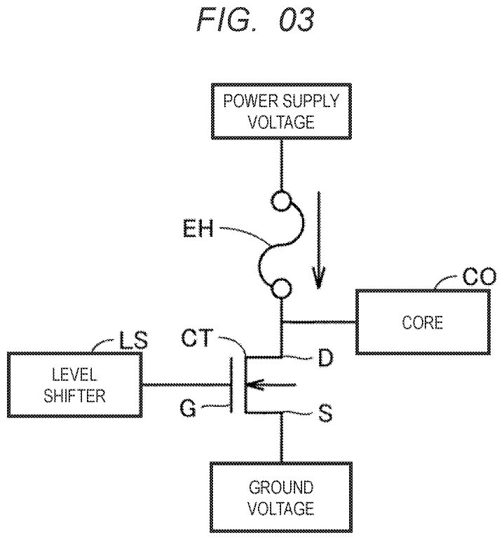

Next, the configuration and function of the redundant circuit portion and the electric fuse will be described with reference to FIGS. 2 and 3.

As shown in FIG. 2, in the semiconductor device SC, a plurality of blocks (specific circuit portion) N1, N2, . . . , Nm are arranged. Each of the plurality of blocks N1, N2, . . . , Nm has the same function. Each of the plurality of blocks N1, N2, . . . , Nm is configured by a plurality of memory cells in the RAM region RA (FIG. 1), for example.

Cuttable fuses H1, H2, . . . , Hm are formed to deactivate each of the plurality of blocks N1, N2, . . . , Nm. A spare redundant block RED having the same function is arranged so as to be able to replace any one of the inactivated blocks N1, N2, . . . , Nm. The redundant block RED is arranged in the redundant circuit region RB shown in FIG. 1.

A potential of the ground power supply GD is applied to the gate electrode of the MOS(Metal Oxide Semiconductor) transistor TR via a fuse Hs. Thus, the MOS transistor TR is held in a non-conducting state. Thus, the redundant block RED is electrically separated in the semiconductor device SC.

In addition, test pad electrodes PDa, PDb are arranged to detect defects in each of the plurality of blocks N1, N2, . . . , Nm.

Next, a functional test of the semiconductor device configured as described above will be described. Here, a case where the fuse is fused and removed by energization will be described.

First, an electric signal from a functional test apparatus (hereinafter also referred to as a tester) not shown is applied via the test pad electrodes PDa, PDb. If the semiconductor device SC is normal, the expected signal for the applied electric signal is output from the test pad electrodes PDa, PDb. At this time, the tester determines whether the semiconductor device SC is good or defective based on the relationship between the electric signal applied to the semiconductor device SC and the electric signal output. If any of the blocks N1, N2, . . . , Nm is determined to be defective, the defective block and the redundant block RED are replaced. This ensures that the semiconductor device SC satisfies the functions that it should achieve, thereby creating a possibility that the semiconductor device SC will be a good product.

The replacement of the defective block and the redundant block RED is performed as follows. When a defect of the block N1 is detected by the above-described functional test, for example, the fuses H1 and Hs are fused and removed by energization. The defective block N1 is electrically separated in the semiconductor device SC due to the fused fuse H1.

On the other hand, by the fused fuse Hs, the voltage of the power supply PV is applied to the gate electrode of the MOS transistor TR via the resistor RR. This causes the MOS transistor TR to become conduction state and the defective block N1 is replaced by the redundant block RED.

Next, the fusing removal of the electric fuse element which is fused and removed by energization will be described with reference to FIG. 3.

As shown in FIG. 3, the electric fuse element EH is a fuse that is cut by flowing a current rather than cutting by irradiating a laser beam. As a switching element for flowing a current to the electric fuse element EH, the cutting transistor CT is provided.

One end of the electric fuse element EH is electrically connected to the power supply voltage (Vdd). The other end of the electric fuse element EH is electrically connected to the drain D of the cutting transistor CT. The source S of the cutting transistor CT is connected to the ground potential (GND).

Level shifter LS is electrically connected to the gate G of the cutting transistor CT. Level shifter LS inputs a signal for turning on and off the cutting transistor CT to the gate G of the cutting transistor CT. To each of the other end of the electric fuse element EH and the drain of the cutting transistor CT, the core portion CO is electrically connected.

If any one of the blocks N1, N2, . . . , Nm (FIG. 2) is determined to be defective, the cutting transistor CT is turned on by the level shifter LS. Thus a current flows through the electric fuse element EH, the electric fuse element EH is fused and removed. The core portion CO is a determination circuit for determining the state of the electric fuse element EH, and if it is determined that the electric fuse element EH has been fused and removed, replacement is performed based on the determination result.

### Configuration of Resistor Element and Electric Fuse Element

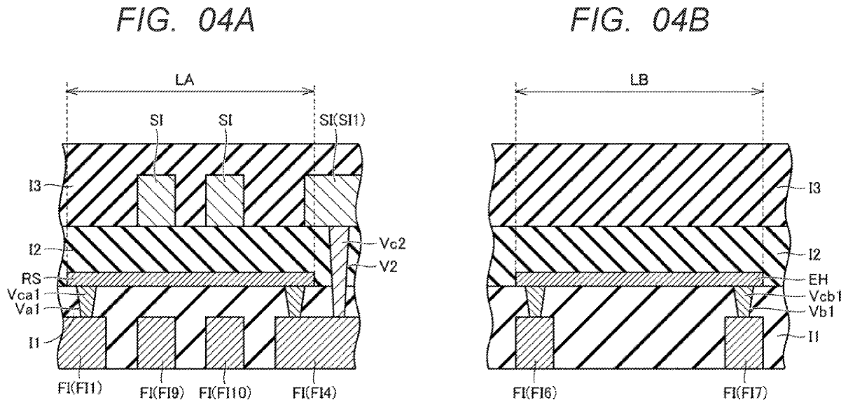

Next, the configuration of the resistor element and the electric fuse element included in the semiconductor device in the present embodiment will be described with reference to FIGS. 4A to 8B. As described above, the resistor element is arranged, for example, in the oscillation circuit region RF in FIG. 1, but the resistor element is not limited thereto and may be arranged in another region.

As shown in FIGS. 4A and 4B, the first wiring FI is arranged on the interlayer dielectric layer (not shown). The first wiring FI is made of a conductor, for example, a metal (including an alloy). The first wiring FI is made of, for example, aluminum (Al), copper (Cu), aluminum-copper (AlCu), and the like. The first wiring FI is an electric wiring that transmits electric signals. However, the first wiring FI may be a dummy wiring. The dummy wiring is a wiring that is electrically isolated from other electric elements and does not transmit electric signals.

As shown in FIG. 4A, the interlayer dielectric layer I1 is arranged so as to cover the first wiring FI. An upper surface of the interlayer dielectric layer I1 is planarized. A via hole Va1 is provided in the interlayer dielectric layer I1. The via hole Va1 reached the first wiring FI from the upper surface of the interlayer dielectric layer I1. In the via hole Va1, a via conductive layer Vca1 is embedded. The via conductive layer Vca1 is made of, for example, tungsten (W).

On the upper surface of the interlayer dielectric layer I1, a resistor element RS (second metal film) is arranged. The resistor element RS is made of, for example, a metal (including an alloy), for example, a silicon metal, nickel chromium (NiCr) or the like. The silicon metal is, for example, silicon chromium (SiCr) or carbon-doped silicon chromium (SiCrC).

Each one end and the other end of the resistor element RS is electrically connected to the first wiring FI via the via conductive layer Vca1. Specifically, one end of the resistor element RS is electrically connected to the first wiring FI1 via the via conductive layer Vca1, the other end of the resistor element RS is electrically connected to the first wiring FI4 via the via conductive layer Vca1.

The interlayer dielectric layer I2 is arranged so as to cover the resistor element RS. An upper surface of the interlayer dielectric layer I2 is planarized. A via hole V2 is provided so as to reach the first wiring FI through the interlayer dielectric layer I2, I1 from the upper surface of the interlayer dielectric layer I2. In the via hole V2, the via conductive layer Vc2 is embedded. The via conductive layer Vc2 is made of, for example, tungsten.

A second wiring SI is arranged on the upper surface of the interlayer dielectric layer I2. The second wiring SI is made of a conductor, for example, a metal (including an alloy). The second wiring SI is made of, for example, aluminum, copper, aluminum-copper, and the like. The second wiring SI is an electric wiring that transmits electric signals. However, the second wiring SI may be a dummy wiring that is electrically isolated from other electric elements and does not transmit an electric signal.

One of the plurality of second wirings SI is electrically connected to the first wiring FI via the via conductive layer Vc2. Specifically, the second wiring SI1 is electrically connected to the first wiring FI4 via the via conductive layer Vc2. An interlayer dielectric layer I3 is arranged so as to cover the second wiring SI. An upper surface of the interlayer dielectric layer I3 is planarized.

As shown in FIG. 4B, the via hole Vb1 is provided in the interlayer dielectric layer I1. The via hole Vb1 reached the first wiring FI from the upper surface of the interlayer dielectric layer I1. In the via hole Vb1, the via conductive layer Vcb1 is embedded. The via conductive layer Vcb1 is made of, for example, tungsten.

On the upper surface of the interlayer dielectric layer I1, an electric fuse element EH (first metal film) is arranged. The electric fuse element EH is made of, for example, a metal (including an alloy) and is made of, for example, silicon metal, nickel chromium or the like. The silicon metal is, for example, silicon chromium, or silicon chromium into which carbon has been introduced.

Each one end and the other end of the electric fuse element EH is electrically connected to the first wiring FI via the via conductive layer Vcb1. Specifically, one end of the electric fuse element EH is electrically connected to the first wiring FI6 via the via conductive layer, and the other end of the electric fuse element EH is electrically connected to the first wiring FI7 via the via conductive layer Vcb1.

An interlayer dielectric layer I2 is arranged so as to cover the electric fuse element EH. An upper surface of the interlayer dielectric layer I2 is planarized. The second wiring SI may be arranged on the upper surface of the interlayer dielectric layer I2. However, it is preferable that the second wiring SI is not arranged in the region directly above the electric fuse element EH. Because the second wiring SI located directly above the electric fuse element EH may be damaged by fusing removal if the electric fuse element EH is fused and removed. An interlayer dielectric layer I3 is arranged on the interlayer dielectric layer I2. An upper surface of the interlayer dielectric layer I3 is planarized as described above.

As shown in FIGS. 4A and 4B, each of the resistor element RS and the electric fuse element EH is arranged in an upper layer of the first wiring FI and in a lower layer of the second wiring SI. The resistor element RS and the electric fuse element EH are arranged in the same layer and have the same composition.

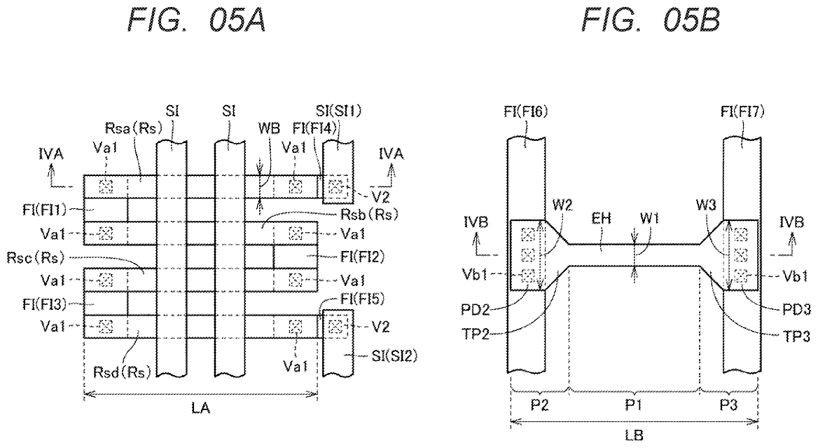

As shown in FIG. 5A, the resistor element RS may include, for example, a plurality of resistor portions RSa, RSb, RSc, and RSd (a plurality of metal portions). Each of the plurality of resistor portions RSa to RSd is made of, for example, a metal (including an alloy) and is made of, for example, silicon metal, nickel chromium, or the like. The silicon metal is, for example, silicon chromium, or silicon chromium into which carbon has been introduced. The resistor element RS is not limited to four resistor portions RSa to RSd, and may have two, three, or five or more resistor portions.

The plurality of resistor portions RSa to RSd may be connected in series. In this case, the plurality of resistor portions RSa to RSd is connected in the order of resistor portion RSa, resistor portion RSb, resistor portion RSc, resistor portion RSd.

Specifically, one end portion of the resistor portion RSa in the longitudinal direction is electrically connected to one end portion of the resistor portion RSb in the longitudinal direction via the first wiring FI1. The other end of the resistor portion RSb in the longitudinal direction is electrically connected to one end of the resistor portion RSc in the longitudinal direction via the first wiring FI2. The other end of the resistor portion RSc in the longitudinal direction is electrically connected to one end of the resistor portion RSd in the longitudinal direction via the first wiring FI3.

The resistor element RS is preferably arranged so as to meander in plan view. The longitudinal direction of each of the plurality of resistor portions RSa to RSd is, for example, along the same direction and is parallel to each other. In such an arrangement, by ends of the resistor portions adjacent to each other in the longitudinal direction are electrically connected via the first wiring FI1 to FI3 as described above, the resistor element RS is configured to meander in plan view.

If the resistor element RS meanders in plan view, the longitudinal direction of each of the plurality of resistor portions RSa to RSd may not be along the same direction to each other.

In plan view, the other end portion of the resistor portion RSa in the longitudinal direction is electrically connected to the second wiring SI1 via the first wiring FI4. Also in plan view, the other end portion of the resistor portion RSd in the longitudinal direction is electrically connected to the second wiring SI2 via the first wiring FI5.

As shown in FIG. 5B, the electric fuse element EH is arranged separately from the resistor element RS. The electric fuse element EH has a first portion P1, a second portion P2, and a third portion P3. The second portion P2 is arranged at one end of the first portion P1. The third portion P3 is arranged at the other end of the first portion P1. The first portion P1 is sandwiched between the second portion P2 and the third portion P3.

At least one portion of each of the second portion P2 and the third portion P3 has a wiring width W2, W3 greater than the wiring width W1 of the first portion P1. In the present embodiment, each of the maximum wiring width W2 of the second portion P2 and the maximum wiring width W3 of the third portion P3 is larger than the wiring width W1 of the first portion P1.

The second portion P2 has a tapered portion TP2 and a pad portion PD2 in plan view. The tapered portion TP2 is connected to the first portion P1. The pad portion PD2 is connected to the tapered portion TP2. The tapered portion TP2 is arranged between the first portion P1 and the pad portion PD2. The tapered portion TP2 is configured such that the wiring width gradually increases from the first portion P1 toward the pad portion PD2 in plan view. The pad portion PD2 has, for example, a rectangular shape in plan view.

Third portion P3 has a tapered portion TP3 and a pad portion PD3 in plan view. The tapered portion TP3 is connected to the first portion P1. The pad portion PD3 is connected to the tapered portion TP3. The tapered portion TP3 is arranged between the first portion P1 and the pad portion PD3. Tapered portion TP3 is configured such that the wiring width gradually increases from the first portion P1 toward the pad portion PD3 in plan view. The pad portion PD3 has, for example, a rectangular shape in plan view. The pad portions PD2, PD3 may be directly connected to the first portion P1 without the tapered portions TP2, TP3.

The pad portion PD2 is electrically connected to the first wiring FI6 via the via hole Vb1. The pad portion PD3 is electrically connected to the first wiring FI7 via the via hole Vb1.

As shown in FIGS. 5A and 5B, the wiring width W1 of the first portion P1 in the electric fuse element EH is smaller than the wiring width WB of each of the plurality of resistor portions RSa to RSd. It is preferable that the wiring widths WB of the plurality of resistor portions RSa to RSd are the same, but they may be different from each other.

As shown in FIGS. 4A and 4B, the wiring length LB of the electric fuse element EH is smaller than the wiring length LA of the resistor element RS. As shown in FIGS. 5A and 5B, when the resistor element RS is formed of a plurality of resistor portions RSa to RSd connected in series, the wiring length LB of the electric fuse element EH is smaller than the sum of the wiring length LA of the plurality of resistor portions RSa to RSd.

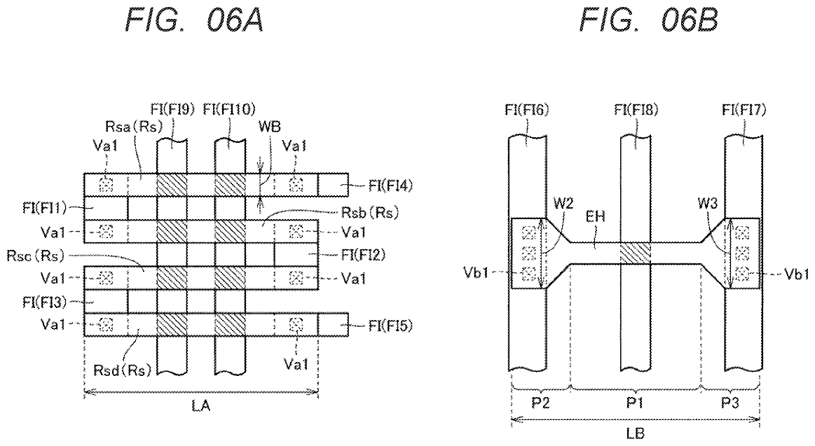

An area of a region (hatching region in the drawing) where the first wiring FI and the electric fuse element EH overlap in plan view as shown in FIG. 6B is smaller than an area of a region (hatching region in the drawing) where the first wiring FI and the resistor element RS overlap in plan view as shown in FIG. 6A. By such reducing the area of the first wiring FI8 overlapping the electric fuse element EH in plan view, the electric fuse element EH is less likely to be radiated, it is likely to be fused.

Incidentally, as shown in FIG. 6A, when there is a plurality of regions where the resistor element RS and the first wiring FI overlap, the sum of the area of the plurality of overlapping regions is compared with the area of the overlapping region between the first wiring FI and the electric fuse element EH. Similarly, when there is a plurality of overlapping regions of the first wiring FI and the electric fuse element EH, the sum of the area of the plurality of overlapping regions is compared with the area of the overlapping region of the first wiring FI and the resistor element RS.

Further, in FIG. 6B, in order to clarify the overlapping region between the electric fuse element EH and the first wiring FI, a configuration in which the first wiring FI8 is provided under the electric fuse element EH is shown. However, in the region directly below the electric fuse element EH, the first wiring FI8 may not be provided as shown in FIGS. 4B and 5B.

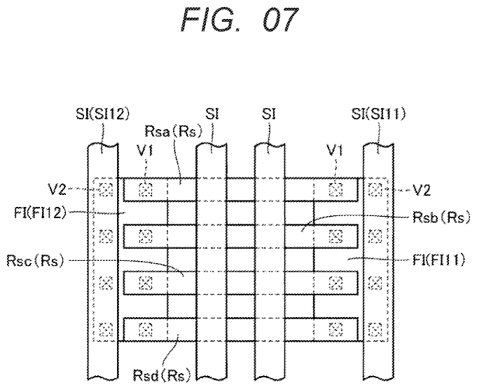

As shown in FIG. 7, when the resistor element RS is formed of the plurality of resistor portions RSa to RSd, the plurality of resistor portions RSa to RSd may be connected in parallel to each other. In this case, the longitudinal directions of each of the plurality of resistor portions RSa to RSd are, for example, along the same direction, are parallel to each other. In such an arrangement, one end portions of the plurality of resistor portions RSa to RSd are electrically connected to each other by a first wiring FI11 via the via hole V1. The other end portions of the plurality of resistor portions RSa to RSd are electrically connected to each other by another first wiring FI12 via the via hole V1. The second wiring SI11 is electrically connected to the first wiring FI11 via the via hole V2. The second wiring SI12 is electrically connected to the first wiring FI12 via the via hole V2.

If the plurality of resistor portions RSa to RSd are connected in parallel with each other, the longitudinal directions of the plurality of resistor portions RSa to RSd may not be along the same direction.

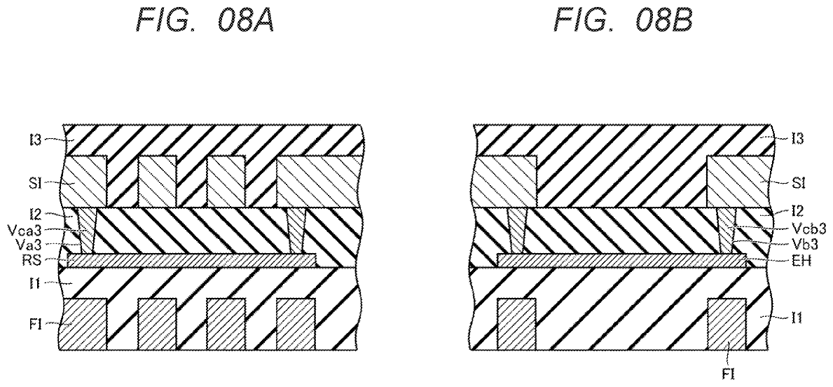

As shown in FIGS. 8A and 8B, each of the resistor element RS and the electric fuse element EH may be electrically connected to the second wiring SI. In this case, the resistor element RS is electrically connected to the second wiring SI by the via conductive layer Vca3 embedded in the via hole Va3 provided in the interlayer dielectric layer I2. The electric fuse element EH is electrically connected to the second wiring SI by the via conductive layer Vcb3 embedded in the via hole Vb3 provided in the interlayer dielectric layer I2.

### Method of Manufacturing Semiconductor Device

Next, a method of manufacturing a semiconductor device of the present embodiment will be described with reference to FIGS. 4A and 9A to 13B.

First, a semiconductor substrate (not shown) is prepared. Electric elements (not shown) such as MOS transistors (not shown) are formed on the surface of the semiconductor substrate. An interlayer dielectric layer is formed on the surface of the semiconductor substrate so as to cover the electric elements formed on the surface of the semiconductor substrate. Wirings are formed on the interlayer dielectric layer. By repeatedly forming the interlayer dielectric layer and the wiring, a multilayer wiring structure is formed.

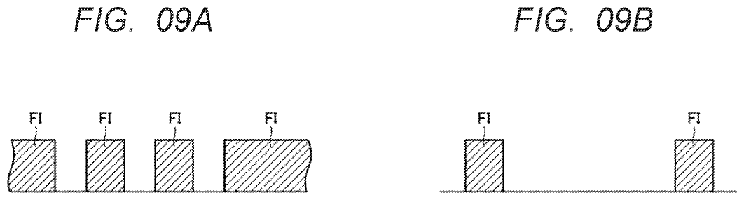

As shown in FIGS. 9A and 9B, as one wiring of the multilayer wiring structure, the first wiring FI is formed. The first wiring FI is formed by, for example, forming a metal (aluminum, copper, aluminum-copper, etc.) on the interlayer dielectric layer, and patterning with a photolithography technique, etching technique, or the like.

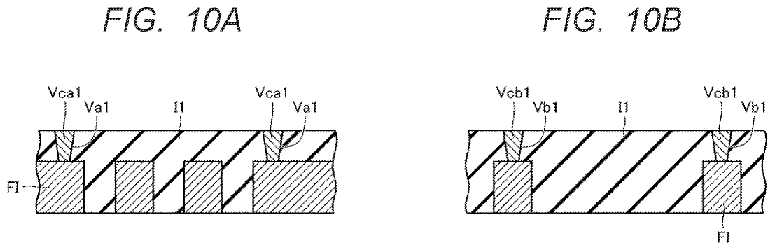

As shown in FIGS. 10A and 10B, the interlayer dielectric layer I1 is formed so as to cover the first wiring FI. The interlayer dielectric layer I1 is made of silicon oxide (SiO₂), for example. After that, CMP (Chemical Mechanical Polishing) is performed. Thus the upper surface of the interlayer dielectric layer I1 is planarized.

Thereafter, the via holes Va1, Vb1 are formed in the interlayer dielectric layer I1 by a photolithography technique. Each of the via holes Va1, Vb1 is formed so as to reach the first wiring FI from the upper surface of the interlayer dielectric layer I1.

Thereafter, the conductive layer for embedding is formed on the upper surface of the interlayer dielectric layer I1 so as to embed each of the via holes Va1, Vb1. The conductive layer for embedding is, for example, tungsten. The barrier metal layer may be formed between the conductive layer for embedding and the interlayer dielectric layer. The barrier metal layer is, for example, titanium nitride (TiN).

Thereafter, CMP is performed on the upper surface of the conductive layer for embedding. Thus the upper surface of the interlayer dielectric layer I1 is exposed, conductive layer for embedding remains inside each of the via holes Va1, Vb1. The via conductive layers Vca1, Vcb1 are formed by the conductive layer for embedding remaining inside each of the via holes Va1, Vb1.

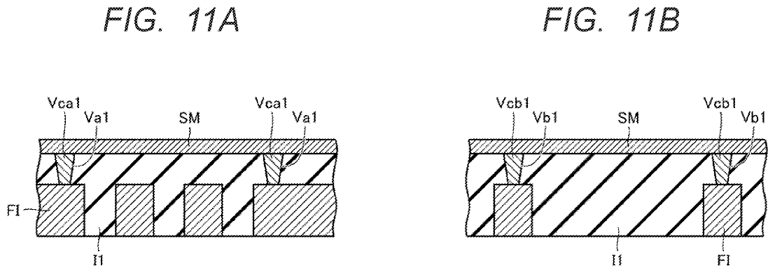

As shown in FIGS. 11A and 11B, a metal layer SM is formed on the upper surface of the interlayer dielectric layer I1, for example by sputtering. The metal layer SM is formed of, for example, a silicon metal (SiCr, SiCrC), nickel chromium, or the like.

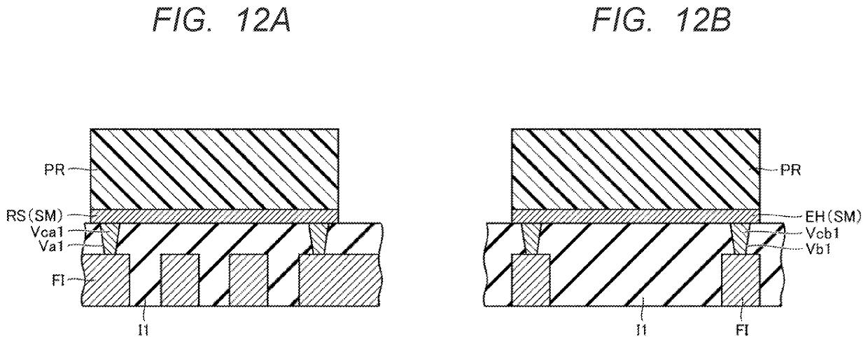

As shown in FIGS. 12A and 12B, a photoresist (organic photosensitive film) PR is applied onto the metal layer SM. The photoresist PR is patterned into a predetermined shape by exposure and development. The metal layer SM is etched using the patterned photoresist PR as a mask.

The metal layer SM is patterned by this etching, the resistor element RS and the electric fuse element EH from the metal layer SM are formed at the same time. The resistor element RS and the electric fuse element EH are formed separately from each other. As a result, the resistor element RS and the electric fuse element EH are formed in the same layer and in the same composition.

The resistor element RS is formed to electrically connect to the first wiring FI via the via conductive layer Vca1 embedded in the via hole Va1. The electric fuse element EH is formed so as to electrically connect to the first wiring FI via the via conductive layer Vcb1 embedded in the via hole Vb1. Thereafter, the photoresist PR is removed by ashing or the like.

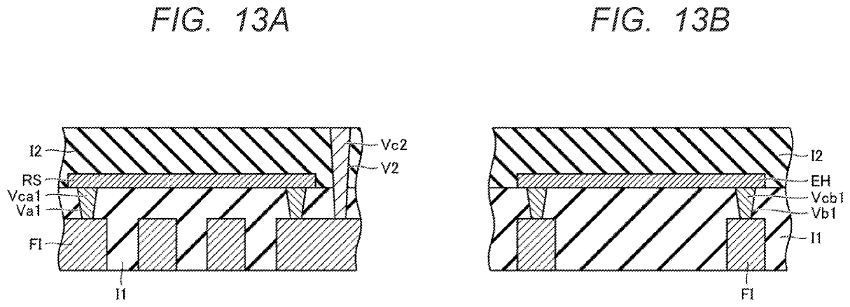

As shown in FIGS. 13A and 13B, after this, the interlayer dielectric layer I2 is formed on the interlayer dielectric layer I1 so as to cover the resistor element RS and the electric fuse. The interlayer dielectric layer I2 is formed of, for example, silicon oxide. Then, CMP is performed on the upper surface of the interlayer dielectric layer I2. Then, the upper surface of the interlayer dielectric layer I2 is planarized.

Thereafter, via holes V2 are formed in the interlayer dielectric layer I1, I2 by photolithography and etching techniques. The via holes V2 are formed so as to reach the first wiring FI from the upper surface of the interlayer dielectric layer I2.

Thereafter, as embedding the via holes V2, the conductive layer for embedding is formed on the upper surface of the interlayer dielectric layer I2. The conductive layer for embedding is, for example, tungsten. The barrier metal layer may be formed between the conductive layer for embedding and the interlayer dielectric layer. The barrier metal layer is, for example, titanium nitride.

Thereafter, CMP is performed on the upper surface of the conductive layer for embedding. Thus the upper surface of the interlayer dielectric layer I2 is exposed, conductive layer for embedding remains inside the via holes V2. The via conductive layer Vc2 is formed by the conductive layer for embedding remaining inside the via hole V2.

As shown in FIGS. 4A and 4B, as one wiring of a multilayer wiring structure, a second wiring SI is formed on the upper surface of the interlayer dielectric layer I2. The second wiring SI is formed by forming a metal (aluminum, copper, aluminum-copper, etc.) on the interlayer dielectric layer I2, and patterning with a photolithography technique, an etching technique, or the like.

An interlayer dielectric layer I3 is formed so as to cover the second wiring SI. The interlayer dielectric layer I3 is formed of, for example, silicon oxide. Then, CMP is performed on the upper surface of the interlayer dielectric layer I3. Thus the upper surface of the interlayer dielectric layer I3 is planarized.

As described above, the semiconductor device of the present embodiment shown in FIGS. 4A and 4B is manufactured.

### Effect

In the present embodiment, the sheet resistance value of silicon metal (silicon chromium) used as the material of the metal films EH and RS is 300 to 1300 Ω/sq., and the melting point is 1306° C. The sheet resistance value of nickel chromium used as the material of the metal films EH and RS is 5 to 200 Ω/sq., and the melting point is 1400° C. On the other hand, the sheet resistance value of polycrystalline silicon is 360 Ω/sq., the melting point is 1414° C. As a result of the above characteristics, silicon metal (silicon chromium) and nickel chromium can be fused with a cutting current smaller than that of polycrystalline silicon.

According to the present embodiment, as shown in FIG. 5B, each of second portion P2 and third portion P3 of the metal film EH has a wider width than first portion P1. Thus, the metal film EH can be used, for example, as the electric fuse element EH. As described above, silicon metal or nickel chromium can be fused with a cutting current lower than that of polycrystalline silicon. Therefore by using the metal film EH for example as an electric fuse element EH, it can be miniaturized cutting transistor CT (FIG. 3). Therefore, the semiconductor device SC of the present embodiment is suitable for miniaturization.

Also shown in FIGS. 5A and 5B, the metal film RS is separated from the metal film EH. Therefore, the metal film RS can be used as an element other than the electric fuse element EH. Silicon metal or nickel chromium has a smaller temperature dependence of resistance compared with polycrystalline silicon. Therefore, by using the metal film RS as, for example, the resistor element RS, the characteristics such as resistance are stabilized.

Silicon metal has a larger sheet resistance than polycrystalline silicon. Thus it is possible to obtain a large resistance in a short wiring length by using a metal film RS, for example, as a resistor element RS, it can be miniaturized in this respect.

The metal film EH and the metal film RS is arranged between the first wiring FI and the second wiring SI. At the time of resin sealing, although stress acts on the metal film EH and the metal film RS due to the difference in thermal expansion coefficients between the sealing resin and the semiconductor substrate, the first wiring FI and the second wiring SI function as a buffer for relaxing stress. Therefore, stresses caused by the difference in thermal expansion coefficients between the sealing resin and the semiconductor substrate at the time of resin sealing hardly act on the metal films RS and EH. For this reason, it is possible to suppress the variation of the characteristics of the element formed by the metal film RS and the element formed by the metal film EH due to the influence of the stress, thereby obtaining stable characteristics.

Thus, it is possible to realize a semiconductor device having stable characteristics and suitable for miniaturization.

According to the present embodiment, the metal film EH is the electric fuse element EH, and the metal film RS is the resistor element RS. Thus in the semiconductor device SC having the electric fuse element EH and the resistor element RS, it is possible to realize a stable characteristic and miniaturization.

Further, according to the present embodiment, as shown in FIG. 5A or FIG. 7, the resistor element RS has a plurality of resistor portions RSa to RSd, and the plurality of resistor portions RSa to RSd is connected in series or in parallel.

Further, according to the present embodiment, as shown in FIG. 5A, a plurality of resistor portions RSa to RSd is connected in series, and the resistor element RS is arranged so as to meander in plan view. Thus, in a small plane occupied area, while reducing wiring width, it is possible to secure a long resistance length.

Further, according to the present embodiment, as shown in FIGS. 6A and 6B, in plan view, the area where the first wiring FI8 and the electric fuse element EH overlap is smaller than the area where the first wiring FI9, FI10 and the resistor element RS overlap. The electric fuse element EH is a portion to be fused and removed. Therefore by reducing the area of the first wiring FI8 overlapping the electric fuse element EH in plan view, the electric fuse element EH is less likely to be radiated, it is likely to be fused.

Further, according to the present embodiment, as shown in FIGS. 4A and 4B, wiring length LB of the electric fuse element EH is smaller than wiring length LA of the resistor element RS. This makes it easy to increase wiring resistance of the resistor element RS. In addition, it becomes easy to specify a portion to be fused and removed in the electric fuse element EH.

Further, according to the present embodiment, as shown in FIGS. 5A and 5B, wiring width W1 of the electric fuse element EH is smaller than wiring width WB of the resistor element RS. This facilitates the fusing removal of the electric fuse element EH.

According to the present embodiment, as shown in FIGS. 5A and 5B, the electric fuse element EH and the resistor element RS are arranged in the same layer and have the same composition. Thus it is possible to form the electric fuse element EH and the resistor element RS from the same layer at the same time. Therefore it is possible to simplify the manufacturing process as compared with the case of forming individually each of the electric fuse element EH and the resistor element RS.

Although the invention made by the present inventor has been specifically described based on the embodiment, the present invention is not limited to the embodiment described above, and it is needless to say that various modifications can be made without departing from the gist thereof.

What is claimed is:

1. A semiconductor device, comprising:
a specific circuit portion;
a spare redundant circuit portion having the same function as the specific circuit portion; and
an electric fuse element that can be a target of fusing removal when replacing the specific circuit portion with the redundant circuit portion,
wherein a material of the electric fuse element includes a silicon metal or nickel chromium.

2. A method of manufacturing a semiconductor device, comprising:
forming a first wiring;
forming a first metal film having a first portion, a second portion arranged on one end of the first portion and a third portion arranged on the other end of the first portion in an upper layer of the first wiring;
forming a second metal film separately from the first metal film in an upper layer of the first wiring; and
forming a second wiring in an upper layer of the first metal film and the second metal film,
wherein a material of each of the first metal film and the second metal film includes silicon metal or nickel chromium,
wherein the first metal film is formed such that each of at least one part of the second portion and at least one part of the third portion has a wiring width larger than a wiring width of the first portion, and
wherein the first metal film and the second metal film are formed at the same time.
